(19) United States
(12) Patent Application Publication
(10) Pub. No.: US 2021/0332472 A1
(43) Pub. Date: Oct. 28, 2021

(54) VACUUM EVAPORATION DEVICE

(71) Applicant: SHENZHEN CHINA STAR OPTOELECTRONICS SEMICONDUCTOR DISPLAY TECHNOLOGY CO.,LTD, Shenzhen (CN)

(72) Inventor: Zhijun Wan, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/617,633

(22) PCT Filed: Nov. 12, 2019
(86) PCT No.: PCT/CN2019/117286

§ 371 Date: Nov. 27, 2019

(30) Foreign Application Priority Data
Sep. 26, 2019 (CN) 201910920287.2

(51) Int. Cl. C23C 14/26

(52) U.S. Cl. CPC C23C 14/26

(57) ABSTRACT

A vacuum evaporation device includes an evaporation chamber formed and sealed by interconnecting a top plate, a bottom plate and a plurality of side plates. The evaporation chamber is provided with an evaporation source and a material recycling device. The recycling structure and the moving structure are combined to recycle the residual material on the evaporation source baffle in the evaporation chamber. Thus, it reduces particle generation, and contamination of the cavity and secondary pollution of recycled materials are avoided. It ensures the health of workers and reduces the cost of material reuse in later stages.

### BACKGROUND OF INVENTION

### Field of Invention

The present invention relates to the technical field of evaporation, and more particularly, to a vacuum evaporation device.

### Description of Prior Art

Currently, vacuum thermal evaporation is widely used for manufacturing organic light emitting diodes (OLED), organic photovoltaic cells (OPV), electrochromic devices (ECD), etc. As for manufacturing the devices, an organic layer or some metal layers are generally formed by an evaporation process.

Most organic materials used for evaporation are expensive. In order to reduce cost, the organic materials are recycled and purified. When the evaporation machine is maintained, components such as internal baffles and adherence prevention plates are disassembled, and the materials attached to the components are collected.

However, when the evaporation machine is working normally, too much material accumulated on the baffle is easily to fall off, which causes contamination of the chamber and increases the number of particles. Therefore, the yield of the product is affected. Moreover, conventional recycling method has problems, such as a slow recycling rate, chamber having a long opening time, and residual material easily accumulates on the baffle, etc.

Therefore, a new vacuum evaporation device is needed to solve the above problems.

### SUMMARY OF INVENTION

The present invention provides a vacuum evaporation device, which can reduce the chamber opening time, reduce particle generation, and avoid contamination of the chamber, so as to solve the problem that the existing vacuum evaporation device has a slow recycling rate, and the number of particles is increased due to long opening time of chamber, which causes contamination of the chamber.

In order to solve the above problems, the technical solutions provided by the present invention are described as follows:

A vacuum evaporation device includes an evaporation chamber formed and sealed by interconnecting a top plate, a bottom plate and a plurality of side plates, and the evaporation chamber is provided with an evaporation source and a material recycling device corresponding to the evaporation source, and the material recycling device includes:

an evaporation source baffle, and the evaporation source baffle is internally provided with a heating resistor ring, the heating resistor ring is configured to heat the evaporation source baffle to detach a residual material when the residual material is attached to a surface of the evaporation source baffle close to a side of the bottom plate; and

a recycling structure, and the recycling structure is coupled to a moving structure, the moving structure is configured to move the recycling structure, and the recycling structure receives the residual material detached from the evaporation source baffle.

In one embodiment, the recycling structure includes:

a recycling container, and the recycling container is provided with an accommodating tank, and the accommodating tank is configured to collect the residual material from the evaporation source baffle; and

a cooling plate, and the cooling plate is disposed at a bottom of the accommodating tank, and the cooling plate is configured to cool detached residual material to make the residual material to be solid to adhere to the accommodating tank.

In one embodiment, the vacuum evaporation device includes a sensor, and the sensor includes a transmitter and a receiver, the transmitter and the receiver are each provided with an indicator light, and the indicator light is red or green;

the emitter is disposed on the evaporation source baffle;

the receiver is disposed outside the recycling container; and

the recycling structure is aligned with the evaporation source baffle through the transmitter and the receiver when the moving structure moves the recycling structure to recycle the residual material.

In one embodiment, a rotating shaft is connected to an end of the evaporation source baffle away from the evaporation source, and the emitter is close to a connection point between the evaporation source baffle and the rotating shaft;

an edge of the recycling container extends in a direction close to the rotating shaft to form a carrying part, and the receiver is disposed on the carrying part;

when the indicator light of the receiver and the indicator light of the transmitter both display red, the rotating shaft rotates the evaporation source baffle, and the moving structure moves the recycling structure to make the evaporation source baffle align with the recycling structure; and

when the indicator light of the receiver and the indicator light of the transmitter both display green, the evaporation source baffle is aligned with the recycling structure.

In one embodiment, the evaporation chamber further includes a recycling cover plate, and the recycling cover plate is configured to cover an opening of the accommodating tank so as to seal the accommodating tank when performing vapor deposition in the evaporation chamber.

In one embodiment, the moving structure is close to one of the side plates, the recycling cover plate is disposed close to a surface of the side plate of the moving structure, and the recycling cover plate is close to the bottom plate; and

when the vapor deposition is performed in the evaporation chamber, the moving structure moves the recycling structure to the recycling cover plate, and the recycling cover plate covers the opening of the accommodating tank so as to seal the accommodating tank.

In one embodiment, the moving structure includes:

a lifter; and

a connecting rod, and one end of the connecting rod is hinged with the lifter, and one end of the connecting rod away from the lifter is connected to the recycling container. The lifter lifts and rotates the connecting rod, the recycling structure recycles the residual material, and the connecting rod drives the recycling structure to move the evaporation source baffle so as to receive the residual material.

In one embodiment, the connecting rod and the recycling container are detachably connected.

In one embodiment, the recycling cover plate is a detachable recycling cover plate.

In one embodiment, a hollow cavity is formed inside the cooling plate, and condensed water passes through the hollow cavity.

A vacuum evaporation device includes an evaporation chamber formed by interconnecting a top plate, a bottom plate and a plurality of side plates, and the evaporation chamber is provided with an evaporation source and a material recycling device corresponding to the evaporation source, and the material recycling device includes:

an evaporation source baffle, and the evaporation source baffle is internally provided with a heating resistor ring, the heating resistor ring is configured to heat the evaporation source baffle to detach the residual material when the residual material is attached to a surface of the evaporation source baffle close to a side of the bottom plate; and

a recycling structure comprising a recycling container and a cooling plate, and the recycling container is provided with an accommodating tank, the cooling plate is disposed at a bottom of the accommodating tank, a hollow cavity is formed inside the cooling plate, and condensed water passes through the hollow cavity; and a moving structure coupled to the recycling structure, and the moving structure is configured to move the recycling structure, and the recycling structure receives the residual material detached from the evaporation source baffle.

In one embodiment, vacuum evaporation device further includes a sensor. The sensor includes a transmitter and a receiver. The transmitter and the receiver are each provided with an indicator light, and the indicator light is red or green. The emitter is disposed on the evaporation source baffle. The receiver is disposed outside the recycling container. The recycling structure is aligned with the evaporation source baffle through the transmitter and the receiver when the moving structure moves the recycling structure to recycle the residual material.

In one embodiment, a rotating shaft is connected to an end of the evaporation source baffle away from the evaporation source, and the emitter is close to a connection point between the evaporation source baffle and the rotating shaft;

an edge of the recycling container extends in a direction close to the rotating shaft to form a carrying part, and the receiver is disposed on the carrying part;

when the indicator light of the receiver and the indicator light of the transmitter both display red, the rotating shaft rotates the evaporation source baffle, and the moving structure moves the recycling structure to make the evaporation source baffle align with the recycling structure; and

when the indicator light of the receiver and the indicator light of the transmitter both display green, the evaporation source baffle is aligned with the recycling structure.

In one embodiment, the evaporation chamber further includes a recycling cover plate, and the recycling cover plate is configured to cover an opening of the accommodating tank so as to seal the accommodating tank when performing vapor deposition in the evaporation chamber.

In one embodiment, the moving structure is close to one of the side plates, the recycling cover plate is disposed close to a surface of the side plate of the moving structure, and the recycling cover plate is close to the bottom plate; and when the vapor deposition is performed in the evaporation chamber, the moving structure moves the recycling structure to the recycling cover plate, and the recycling cover plate covers the opening of the accommodating tank so as to seal the accommodating tank.

In one embodiment, the moving structure includes:

a lifter; and

a connecting rod, and one end of the connecting rod is hinged with the lifter, and one end of the connecting rod away from the lifter is connected to the recycling container. The lifter lifts and rotates the connecting rod, the recycling structure recycles the residual material, and the connecting rod drives the recycling structure to move the evaporation source baffle so as to receive the residual material.

In one embodiment, the connecting rod and the recycling container are detachably connected.

In one embodiment, the recycling cover plate is a detachable recycling cover plate.

A vacuum evaporation device includes an evaporation chamber formed by interconnecting a top plate, a bottom plate and a plurality of side plates, and the evaporation chamber is provided with an evaporation source and a material recycling device corresponding to the evaporation source, and the material recycling device includes:

an evaporation source baffle, and the evaporation source baffle is internally provided with a heating resistor ring, the heating resistor ring is configured to heat the evaporation source baffle to detach the residual material when the residual material is attached to a surface of the evaporation source baffle close to a side of the bottom plate; and

a recycling structure including a recycling container and a cooling plate, and the recycling container is provided with an accommodating tank, the cooling plate is disposed at a bottom of the accommodating tank, a hollow cavity is formed inside the cooling plate, and condensed water passes through the hollow cavity; and

a moving structure comprising a lifter and a connecting rod, and one end of the connecting rod is hinged with the lifter, and one end of the connecting rod away from lifter is connected to the recycling container.

In one embodiment, the vacuum evaporation device further includes a sensor, and the sensor includes a transmitter and a receiver, the transmitter and the receiver are each provided with an indicator light, and the indicator light is red or green. The emitter is disposed on the evaporation source baffle. The receiver is disposed outside the recycling container. The recycling structure is aligned with the evaporation source baffle through the transmitter and the receiver when the moving structure moves the recycling structure to recycle the residual material.

Advantageous effects of the present invention are described as follows. A vacuum evaporation device includes an evaporation chamber formed and sealed by interconnecting a top plate, a bottom plate and a plurality of side plates. The evaporation chamber is provided with an evaporation source and a material recycling device corresponding to the evaporation source, and the material recycling device includes: an evaporation source baffle, and the evaporation source baffle is internally provided with a heating resistor ring; and a recycling structure, and the recycling structure is coupled to a moving structure, the moving structure is configured to move the recycling structure. When the residual material is attached to the evaporation source baffle, the heating resistor ring heats the evaporation source baffle to disengage the residual material from the evaporation source baffle. At the same time, the moving structure moves the recycling structure to receive the residual material. The present invention combines the recycling structure and the moving structure to recycle the residual material on the evaporation source baffle in the evaporation chamber. When recycling, it is not necessary to open the evaporation chamber for a long time, and the foreign matter is prevented from entering the cavity, thereby reducing particle generation. Thus. contamination of the cavity and secondary pollution of recycled materials are avoided, and it ensures the health of workers and reduces the cost of material reuse in later stages.

### BRIEF DESCRIPTION OF DRAWINGS

In order to more clearly illustrate the technical solutions in the embodiments, the drawings described in the description of the embodiments are briefly described below. It is obvious that the drawings in the following description are only some embodiments of the present invention. Other drawings can also be obtained from those skilled persons in the art based on drawings without any creative effort.

FIG. 1 is a schematic view of a material recycling component of a vacuum evaporation device according to a first embodiment of the present invention.

FIG. 2 is a schematic view of a material recycling device of the vacuum evaporation device according to a second embodiment of the present invention.

FIG. 3 is a schematic view of a vacuum evaporation device according to one embodiment of the present invention.

FIG. 4 is a top plan view of the vacuum evaporation device according to one embodiment of the present invention.

FIG. 5 is a top plan view of the vacuum evaporation device according to one embodiment of the present invention.

### DETAILED DESCRIPTION OF PREFERRED EMBODIMENTS

The following description of the various embodiments is provided to illustrate the specific embodiments of the invention. Directional terms mentioned in this application, such as “up,” “down,” “forward,” “backward,” “left,” “right,” “inside,” “outside,” “side,” etc., are merely indicated the direction of the drawings. Therefore, the directional terms are used for illustrating and understanding of the application rather than limiting thereof. In the drawings, structurally similar elements are denoted by the same reference numerals.

The present invention is capable of solving the technical problem in the conventional vacuum evaporation such as a slow recycling rate, a long opening time, an increase in the number of particles, and contamination of the cavity.

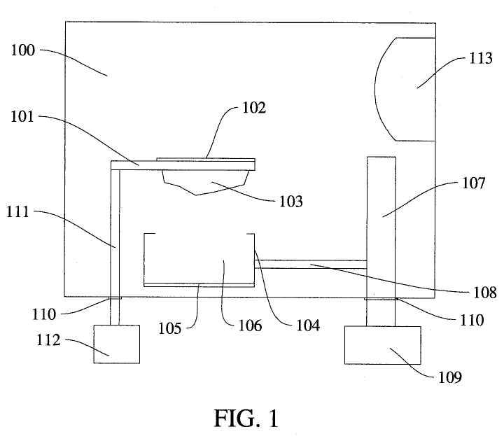

Referring to FIG. 1, in one embodiment, a vacuum evaporation device is provided. The vacuum evaporation device includes an evaporation chamber 100 formed by interconnecting a top plate, a bottom plate and a plurality of side plates. The evaporation chamber 100 is provided with an evaporation source and a material recycle device corresponding to the evaporation source. The material recycling device includes: an evaporation source baffle 101, and the interior of the evaporation source baffle 101 is a hollow structure, and the hollow structure is provided with a heating resistor ring 102, and the heating resistor ring 102 is configured to heat the evaporation source baffle 101 to detach the residual material 103 when the residual material 103 is attached to a surface of the evaporation source baffle 101 close to a side of the bottom plate; and a recycling structure. The recycling structure is coupled to a moving structure, the moving structure is configured to move the recycling structure, and the recycling structure receives the residual material 103 detached from the evaporation source baffle 101.

The recycling structure includes a recycling container 104 and a cooling plate 105. The recycling container 104 is provided with an accommodating tank 106. The cooling plate 105 is disposed at a bottom of the accommodating tank 106. The cooling plate 105 may be a structure in which a hollow cavity is formed inside, and condensed water passes through the hollow cavity. When the residual material 103 is recycled, the cooling plate 105 may rapidly cool the residual material 103 into a solid state, so that the residual material 103 is easily attached to the accommodating tank 106. It should be noted that the opening of the accommodating tank 106 may be larger than the range in which the residual material 103 is attached, and when the residual material 103 is recycled, it is ensured that the residual material 103 completely enters the accommodating tank 106.

The moving structure includes a lifter 107 and a connecting rod 108. The lifter 107 may be a cylindrical shape. A driving device 109 is connected to one end of the lifter 107 through the bottom plate.

The driving device 109 may be a hydraulic device or a pneumatic device, etc., and the driving device 109 may also be a roller sliding device. One end of the connecting rod 108 is hinged with the lifter 107, and one end of the connecting rod 108 away from lifter 107 is connected to the recycling container. The connecting rod 108 has a function to connect the lifter 107 and the recycling structure. When the residual material 103 is recycled, recycled structure can be moved by the connecting rod 108 which is driven by the lifter 107. The connecting rod 108 can be a straight rod or a rod having two segments that are angled and connected to each other. The connecting point of the connecting rod 108 and the lifter 107 may be provided with a screw or a cutting shaft so as to facilitate the rotation of the connecting rod 108. Thus, the recycling structure can be moved more quickly.

The outer side of the lifter 107 may be covered with an outer casing, and the outer casing may be made of stainless steel, and a portion of the outer casing located outside the evaporation chamber 100 and the bottom plate are connected by a screw. The outer casing and the screw are removable. When the moving structure needs to be periodically replaced and cleaned, only the outer casing may be removed for replacement cleaning. A seal ring 110 may be disposed at the connection of the lifter 107 and the bottom plate, and the sealing ring 110 should completely seal the gap at the connection, so that the vapor deposition chamber 100 can be evacuated, and the vapor deposition can be performed in the evaporation chamber 100.

One end of the evaporation source baffle 101 may be connected to a rotating shaft 111, and the rotating shaft 111 may be connected to the motor 112 through the bottom plate, and the rotating shaft 111 is driven by the motor 112 to rotate the evaporation source baffle 101. When the residual material 103 is recycled, the evaporation source baffle 101 can be made by a suitable movement value while the rotating shaft 111 rotates the evaporation source baffle 101 and the moving structure moves the recycling structure. The evaporation source baffle 101 and the recovery structure are in a relatively vertical position, and a proper vertical distance between the evaporation source baffle 101 and the recycling structure is required to ensure that the residual material 103 can smoothly enter the accommodating tank 106. The sealing ring 110 can also be disposed at the connection between the rotating shaft 111 and the bottom plate, and the sealing ring 110 should completely seal the gap at the connection, so that the vapor deposition chamber 100 can be evacuated, and the vapor deposition can be performed in the evaporation chamber 100.

It should be noted that if the residual material 103 is heated, it is converted from a solid state to a liquid state, or after the residual material 103 is heated, the adhesion force is reduced, and it can be automatically detached from the evaporation source baffle 101, and there is a vertical distance between the evaporation source baffle 101 and the recycling structure. However, in some cases, for example, after the heating resistor ring 102 heats the evaporation source baffle 101, the residual material 103 may be directly sublimated from a solid state to a gaseous state. At this time, before the heating of the residual material 103, the evaporation source baffle 101 and a recycling container 104 are moved to a corresponding position by a suitable movement value, and the evaporation source baffle 101 should cover an opening of the accommodating tank 106 to form a closed cavity, and the residual material 103 attached to the evaporation source baffle 101 needs to be entirely in the closed cavity.

When vapor deposition is performed in the evaporation chamber 100, the vapor deposition chamber 100 needs to be evacuated. When the residual material 103 has been recycled in the accommodating tank 106, the powder of the residual material 103 is easily driven away from the accommodating tank 106 by the air pressure during vacuuming, and the residual material 106 is dispersed in the evaporation chamber 100, which results that the evaporation chamber 100 is contaminated. Therefore, a recycling cover plate 113 may be provided to prevent the above-mentioned problems from occurring. The moving structure is close to one of the side plates, the recycling cover plate 113 is disposed close to a surface of the side plate of the moving structure, and the recycling cover plate 113 is close to the bottom plate. The recycling cover plate 113 covers the opening of the accommodating tank 106 so as to seal the accommodating tank 106.

It should be noted that the connecting rod 108 and the recycling container 104 are detachably connected. When enough residual material 103 is collected in the recycling container 104, the recycling container 104 needs to be processed, in which case the recycling container 104 only needs to be disassembled, and the residual material 103 in the recycling container 104 may be recycled for reuse.

In the embodiment, the recycling container 104 is a rectangular parallelepiped. In other embodiments, the recycling container 104 may also have other shapes, such as pot shape, cup shape, or a polygon with curved sides, etc. The recycling container 104 only needs to provide an accommodating tank 106 for accommodating the residual material 103, so that the residual material 103 can completely fall into the recycling container 104 after being detached from the evaporation source baffle 101.

In the embodiment, a vacuum evaporation device is provided. A plurality of the evaporation source baffle 101 may be disposed in the evaporation chamber 100, and each of the evaporation source baffles 101 may be provided with an adherence prevention plate underneath. The residual material 103 is also easily formed on the adherence prevention plate, and each of the evaporation source baffle 101 and the adherence prevention plate correspond to one of the recycling structures. When a plurality of recovery structures are disposed in the evaporation chamber 100, it is necessary to clarify that other structures related to the recycling structure, such as the moving structure, the recycling cover plate 113, etc., are also plural, which correspond to each of the recycling structures.

In the first embodiment, a vacuum evaporation device is provided. The vacuum evaporation device includes a recycling structure and a moving structure. The recycling structure is composed of a recycling container and a cooling plate. When the residual material is attached to the evaporation source baffle and needs to be recycled, the evaporation source baffle is rotated and the recycling structure is moved through suitable movement value. Therefore, the evaporation source baffle and the recycling structure are located at opposite positions with a proper vertical distance therebetween to ensure that the recycling structure can receive residual material when the heating resistor ring on the evaporation source baffle heats the evaporation source baffle to remove the residual material, and make the residual material cool quickly and adhere to the inside of the recycling container.

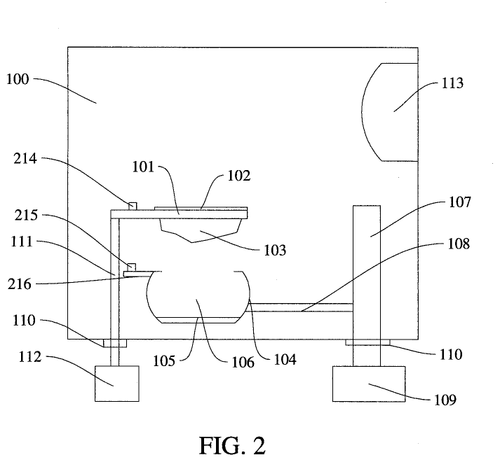

Referring to FIG. 2 a vacuum evaporation device provided by the second embodiment of the present invention is different from the first embodiment in that the vacuum evaporation device further includes a sensor, and the sensor includes a transmitter 214 and a receiver 215, and the sensor may be an optical sensor, and the transmitter 214 and the receiver 215 are respectively disposed near the evaporation source baffle 101 and outside the recycling container. For example, the emitter 214 is disposed on the evaporation source baffle 101, and the receiver 215 is disposed outside the recycling container 104. For another example, the receiver 215 is disposed on the rotating shaft 111, and the transmitter 214 is disposed outside the recycling container 104.

Specifically, the moving structure is close to a side plate, and the recycling container 104 may extend at an edge away from the moving structure to form a carrying part 216, and the receiver 215 or the transmitter 214 is disposed on the carrying part 216.

The transmitter 214 and the receiver 215 are each provided with an indicator light, and the indicator light is red or green. When the residual material 103 is recycled, the indicator light of the transmitter 214 and the indicator light of the receiver 215 both display red. The rotating shaft 111 rotates the evaporation source baffle 101, the moving structure moves the recycling structure, and the evaporation source baffle 101 and the recycling structure are aligned by the emitter 214 and the receiver 215, which ensures that the evaporation source baffle 101 and the recycling structure are located at corresponding positions and maintain a proper vertical distance between each other. When the indicator light of the transmitter 214 and the indicator light of the receiver 215 both display green, the evaporation source baffle 101 is aligned with the recycling structure. It should be noted that the optical sensor performs alignment by receiving a signal after the software sends a signal.

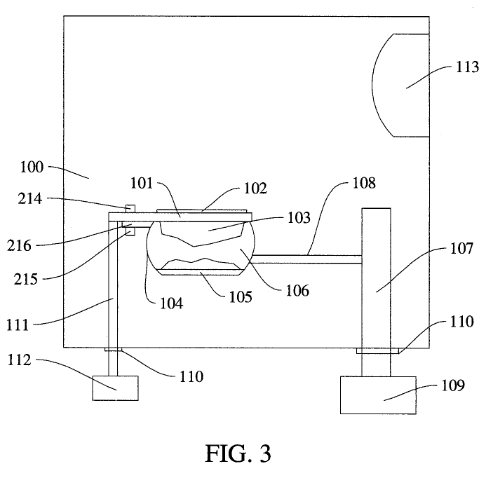

It should be noted that if the residual material 103 is heated, it is converted from a solid state to a liquid state, or after the residual material 103 is heated, the adhesion force is reduced, and it can be automatically detached from the evaporation source baffle 101, and there is a vertical distance between the evaporation source baffle 101 and the recycling structure. However, in some cases, for example, after the heating resistor ring 102 heats the evaporation source baffle 101, the residual material 103 may be directly sublimated from a solid state to a gaseous state. Referring to FIG. 3, before the heating of the residual material 103, the evaporation source baffle 101 aligns with the recycling structure 104 by the transmitter 214 and the receiver 215. The evaporation source baffle 101 covers an opening of the accommodating tank 106 to form a closed cavity, and the residual material 103 attached to the evaporation source baffle 101 needs to be entirely in the closed cavity.

In the embodiment, the recycling container 104 is a polygon. In other embodiments, the recycling container 104 may also have other shapes, such as pot shape, cup shape, or a rectangular parallelepiped, etc. The recycling container 104 only needs to provide an accommodating tank 106 for accommodating the residual material 103, so that the residual material 103 can completely fall into the recycling container 104 after being detached from the evaporation source baffle 101.

In the embodiment, a vacuum evaporation device is provided. A plurality of the evaporation source baffle 101 may be disposed in the evaporation chamber 100, and each of the evaporation source baffles 101 may be provided with an adherence prevention plate underneath. The residual material 103 is also easily formed on the adherence prevention plate, and each of the evaporation source baffle 101 and the adherence prevention plate correspond to one of the recycling structures. When a plurality of recovery structures are disposed in the evaporation chamber 100, it is necessary to clarify that other structures related to the recycling structure, such as the moving structure, the recycling cover plate 113, etc., are also plural, which correspond to each of the recycling structures.

In the second embodiment, a vacuum evaporation device is provided. On the basis of the first embodiment, an optical sensor is added, and the optical sensor includes two parts, such as a transmitter and a receiver, which are respectively disposed on the evaporation source baffle or the rotating shaft and outside of the recycling container. The optical sensor can ensure the accurate alignment between the evaporation source baffle and the recycling container. When the recycling structure recycles the residual material, the evaporation source baffle aligns with the recycling container by the emitter and the receiver, which can improve recycling rate of the residual material.

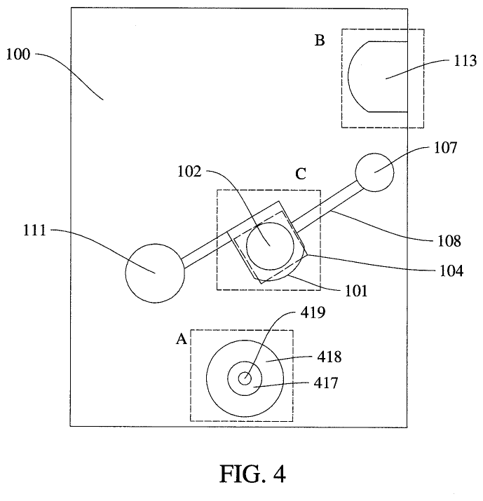

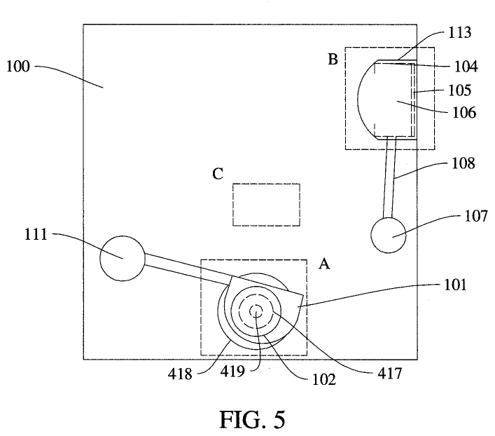

Referring to FIG. 4 and FIG. 5, the technical solutions of the present invention are specifically described below by the working steps of the respective structures of the vacuum evaporation device in two different states.

In the vacuum evaporation device, the evaporation source includes a crucible 417 and a heat insulation layer 418. The heat insulation layer 418 is disposed at outside of the crucible 417. A heating resistor ring (not shown) may be disposed between the heat insulation layer 418 and the crucible 417. The crucible 417 is configured to hold an evaporation material 419 that needs to be evaporated. When the evaporation material 419 is evaporated, the evaporation source baffle 101 is located above the evaporation source. A substrate, which is needed to be evaporated, is placed above the evaporation source baffle 101, and an opening may be formed in the evaporation source baffle 101, and the evaporation material 419 can pass through the opening. The evaporation material 419 contacts with the substrate to form a film after passing through the opening of the evaporation source baffle 101. A part of evaporation material 419 contacts with the evaporation source baffle 101 and the adherence prevention plate before passing through the opening, and is easily solidified under the evaporation source baffle 101 or the adherence prevention plate to form the residual material 103. Alternatively, when the evaporation is completed, a part of the evaporation material 419 fails to pass through the opening, and is collected under the evaporation source baffle 101 or the adherence prevention plate. When the evaporation source is in a cooling state, the ambient temperature is lowered, and the part of evaporation material 419 is solidified and adhered to the evaporation source baffle 101 or the adherence prevention plate to form the residual material 103. It can be known that when the residual material 103 is attached to the evaporation source baffle 101 or the surface of the adherence prevention plate, a range of attachment of the residual material 103 should not exceed the evaporation range of the evaporation source.

Referring to FIG. 4, the evaporation source is in a cooling or shutdown state, and a certain amount of the residual material 103 is attached to the evaporation source baffle 101, and positions of the evaporation source baffle 101 and the recycling structure are determined by a suitable movement value or a sensor. At this time, the evaporation source shutter 101 is rotated from “A” position to “C” position by the rotating shaft 111, and a recycling cover plate 113 is opened. The lifter 107 starts to work, and the lifter 107 moves the recycling structure from “B” position to “C” position by the connecting rod 108. Then, the evaporation source baffle 101 slightly aligns with the recycling structure. After the alignment is completed, the heating resistor ring 102 is turned on to heat the evaporation source baffle 101. After the residual material 103 is heated, it is detached from the evaporation source baffle 101. The residual material 103 detached from the evaporation source baffle 101 enters the recycling container 104, and is cooled and solidified by the cooling plate 105, and adheres to the accommodating tank 106.

Referring to FIG. 5, the evaporation source needs to start working, or the residual material 103 has been recycled. At this time, the heating resistor ring 102 is turned off, and the rotating shaft 111 rotates the evaporation source baffle 101 from “C” position to “A” position, and the evaporation source baffle 101 is stopped above the evaporation source to facilitate the next start of operation of the evaporation source. The lifter 107 moves the recycling structure from “C” position to B position by the connecting rod 108, the bottom of the recycling container 104 is close to the side plate, and the recycling cover plate 113 covers the recycling container 104 so as to seal the accommodating tank 106.

Advantageous effects of the present invention are described as follows. A vacuum evaporation device includes an evaporation chamber formed and sealed by interconnecting a top plate, a bottom plate and a plurality of side plates. The evaporation chamber is provided with an evaporation source and a material recycling device corresponding to the evaporation source, and the material recycling device includes: an evaporation source baffle, and the evaporation source baffle is internally provided with a heating resistor ring; and a recycling structure, and the recycling structure is coupled to a moving structure, the moving structure is configured to move the recycling structure. When the residual material is attached to the evaporation source baffle, the heating resistor ring heats the evaporation source baffle to disengage the residual material from the evaporation source baffle. At the same time, the moving structure moves the recycling structure to receive the residual material. The present invention combines the recycling structure and the moving structure to recycle the residual material on the evaporation source baffle in the evaporation chamber. When recycling, it is not necessary to open the evaporation chamber for a long time, and the foreign matter is prevented from entering the cavity, thereby reducing particle generation. Thus. contamination of the cavity and secondary pollution of recycled materials are avoided, and ensures the health of workers and reduces the cost of material reuse in later stages.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. A vacuum evaporation device, comprising an evaporation chamber formed and sealed by interconnecting a top plate, a bottom plate and a plurality of side plates, wherein the evaporation chamber is provided with an evaporation source and a material recycling device corresponding to the evaporation source, and the material recycling device comprises:
an evaporation source baffle, wherein the evaporation source baffle is internally provided with a heating resistor ring, the heating resistor ring is configured to heat the evaporation source baffle to detach a residual material when the residual material is attached to a surface of the evaporation source baffle close to a side of the bottom plate; and
a recycling structure, wherein the recycling structure is coupled to a moving structure, the moving structure is configured to move the recycling structure, and the recycling structure receives the residual material detached from the evaporation source baffle.

2. The vacuum evaporation device according to claim 1, wherein the recycling structure comprises:
a recycling container, wherein the recycling container is provided with an accommodating tank, and the accommodating tank is configured to collect the residual material from the evaporation source baffle; and
a cooling plate, wherein the cooling plate is disposed at a bottom of the accommodating tank, and the cooling plate is configured to cool detached residual material to make the residual material to be solid to adhere to the accommodating tank.

3. The vacuum evaporation device according to claim 2, further comprising a sensor, wherein the sensor comprises a transmitter and a receiver, the transmitter and the receiver are each provided with an indicator light, and the indicator light is red or green;
the emitter is disposed on the evaporation source baffle;
the receiver is disposed outside the recycling container; and
the recycling structure is aligned with the evaporation source baffle through the transmitter and the receiver when the moving structure moves the recycling structure to recycle the residual material.

4. The vacuum evaporation device according to claim 2, wherein a rotating shaft is connected to an end of the evaporation source baffle away from the evaporation source, and the emitter is close to a connection point between the evaporation source baffle and the rotating shaft;
an edge of the recycling container extends in a direction close to the rotating shaft to form a carrying part, and the receiver is disposed on the carrying part;
when the indicator light of the receiver and the indicator light of the transmitter both display red, the rotating shaft rotates the evaporation source baffle, and the moving structure moves the recycling structure to make the evaporation source baffle align with the recycling structure; and
when the indicator light of the receiver and the indicator light of the transmitter both display green, the evaporation source baffle is aligned with the recycling structure.

5. The vacuum evaporation device according to claim 2, wherein the evaporation chamber further comprises a recycling cover plate, and the recycling cover plate is configured to cover an opening of the accommodating tank so as to seal the accommodating tank when performing vapor deposition in the evaporation chamber.

6. The vacuum evaporation device according to claim 5, wherein the moving structure is close to one of the side plates, the recycling cover plate is disposed close to a surface of the side plate of the moving structure, and the recycling cover plate is close to the bottom plate; and
when the vapor deposition is performed in the evaporation chamber, the moving structure moves the recycling structure to the recycling cover plate, and the recycling cover plate covers the opening of the accommodating tank so as to seal the accommodating tank.

7. The vacuum evaporation device according to claim 2, wherein the moving structure comprises:
a lifter; and
a connecting rod, wherein one end of the connecting rod is hinged with the lifter, and one end of the connecting rod away from lifter is connected to the recycling container;
wherein the lifter lifts and rotates the connecting rod, the recycling structure recycles the residual material, and the connecting rod drives the recycling structure to move the evaporation source baffle so as to receive the residual material.

8. The vacuum evaporation device according to claim 7, wherein the connecting rod and the recycling container are detachably connected.

9. The vacuum evaporation device according to claim 7, wherein the recycling cover plate is a detachable recycling cover plate.

10. The vacuum evaporation device according to claim 2, wherein a hollow cavity is formed inside the cooling plate, and condensed water passes through the hollow cavity.

11. A vacuum evaporation device, comprising an evaporation chamber formed by interconnecting a top plate, a bottom plate and a plurality of side plates, wherein the evaporation chamber is provided with an evaporation source and a material recycling device corresponding to the evaporation source, and the material recycling device comprises:
an evaporation source baffle, wherein the evaporation source baffle is internally provided with a heating resistor ring, the heating resistor ring is configured to heat the evaporation source baffle to detach the residual material when the residual material is attached to a surface of the evaporation source baffle close to a side of the bottom plate; and
a recycling structure comprising a recycling container and a cooling plate, wherein the recycling container is provided with an accommodating tank, the cooling plate is disposed at a bottom of the accommodating tank, a hollow cavity is formed inside the cooling plate, and condensed water passes through the hollow cavity; and
a moving structure coupled to the recycling structure, wherein the moving structure is configured to move the recycling structure, and the recycling structure receives the residual material detached from the evaporation source baffle.

12. The vacuum evaporation device according to claim 11, further comprising a sensor, wherein the sensor comprises a transmitter and a receiver, the transmitter and the receiver are each provided with an indicator light, and the indicator light is red or green;
the emitter is disposed on the evaporation source baffle;
the receiver is disposed outside the recycling container; and
the recycling structure is aligned with the evaporation source baffle through the transmitter and the receiver when the moving structure moves the recycling structure to recycle the residual material.

13. The vacuum evaporation device according to claim 12, wherein a rotating shaft is connected to an end of the evaporation source baffle away from the evaporation source, and the emitter is close to a connection point between the evaporation source baffle and the rotating shaft;
an edge of the recycling container extends in a direction close to the rotating shaft to form a carrying part, and the receiver is disposed on the carrying part;
when the indicator light of the receiver and the indicator light of the transmitter both display red, the rotating shaft rotates the evaporation source baffle, and the moving structure moves the recycling structure to make the evaporation source baffle align with the recycling structure; and
when the indicator light of the receiver and the indicator light of the transmitter both display green, the evaporation source baffle is aligned with the recycling structure.

14. The vacuum evaporation device according to claim 11, wherein the evaporation chamber further comprises a recycling cover plate, and the recycling cover plate is configured to cover an opening of the accommodating tank so as to seal the accommodating tank when performing vapor deposition in the evaporation chamber.

15. The vacuum evaporation device according to claim 14, wherein the moving structure is close to one of the side plates, the recycling cover plate is disposed close to a surface of the side plate of the moving structure, and the recycling cover plate is close to the bottom plate; and
when the vapor deposition is performed in the evaporation chamber, the moving structure moves the recycling structure to the recycling cover plate, and the recycling cover plate covers the opening of the accommodating tank so as to seal the accommodating tank.

16. The vacuum evaporation device according to claim 11, wherein the moving structure comprises:
a lifter; and
a connecting rod, wherein one end of the connecting rod is hinged with the lifter, and one end of the connecting rod away from the lifter is connected to the recycling container;
wherein the lifter lifts and rotates the connecting rod, the recycling structure recycles the residual material, and the connecting rod drives the recycling structure to move the evaporation source baffle so as to receive the residual material.

17. The vacuum evaporation device according to claim 16, wherein the connecting rod and the recycling container are detachably connected.

18. The vacuum evaporation device according to claim 17, wherein the recycling cover plate is a detachable recycling cover plate.

19. A vacuum evaporation device, comprising an evaporation chamber formed by interconnecting a top plate, a bottom plate and a plurality of side plates, wherein the evaporation chamber is provided with an evaporation source and a material recycling device corresponding to the evaporation source, and the material recycling device comprises:
an evaporation source baffle, wherein the evaporation source baffle is internally provided with a heating resistor ring, the heating resistor ring is configured to heat the evaporation source baffle to detach the residual material when the residual material is attached to a surface of the evaporation source baffle close to a side of the bottom plate; and
a recycling structure comprising a recycling container and a cooling plate, wherein the recycling container is provided with an accommodating tank, the cooling plate is disposed at a bottom of the accommodating tank, a hollow cavity is formed inside the cooling plate, and condensed water passes through the hollow cavity; and
a moving structure comprising a lifter and a connecting rod, wherein one end of the connecting rod is hinged with the lifter, and one end of the connecting rod away from lifter is connected to the recycling container.

20. The vacuum evaporation device according to claim 19, further comprising a sensor, wherein the sensor comprises a transmitter and a receiver, the transmitter and the receiver are each provided with an indicator light, and the indicator light is red or green;
the emitter is disposed on the evaporation source baffle;
the receiver is disposed outside the recycling container; and
the recycling structure is aligned with the evaporation source baffle through the transmitter and the receiver when the moving structure moves the recycling structure to recycle the residual material.
